(19) United States
(12) Patent Application Publication
(10) Pub. No.: US 2024/0275090 A1
(43) Pub. Date: Aug. 15, 2024

(54) CARD EDGE CONNECTOR AND ELECTRONIC SYSTEM

(71) Applicant: Amphenol Commercial Products (Chengdu) Co., Ltd., Chengdu (CN)

(72) Inventors: Kui Yang, Chengdu (CN); Xiaodong Hu, Chengdu (CN)

(73) Assignee: Amphenol Commercial Products (Chengdu) Co., Ltd., Chengdu (CN)

(21) Appl. No.: 18/436,117

(22) Filed: Feb. 8, 2024

(30) Foreign Application Priority Data
Feb. 9, 2023 (CN) 202310108937.X
Feb. 9, 2023 (CN) 202320204779.3

(51) Int. Cl. H01R 12/72; H01R 12/70; H01R 13/502; H01R 13/629

(52) U.S. Cl. CPC H01R 12/721; H01R 12/7058; H01R 13/502; H01R 13/62988

(57) ABSTRACT

A connector for high density, high speed, and high performance electronic systems. The connector has multiple slots, each of which can receive a card. Terminals disposed on opposite sides of each slot connect the card inserted therein to a motherboard on which the connector is mounted. Each slot has a latch disposed at an end for retaining the card inserted therein when the latch is locked and releasing the card from the slot when the latch is unlocked. The connector has a reinforcing members configured to enhance the mechanical strength of the housing. Terminal tails are configured for solder ball attachments such that the terminals of adjacent slots are disposed closer. The tails are also configured such that a smaller solder area is needed on the motherboard. Such configurations improve signal integrity at higher speed and increases the tolerance of errors in the manufacturing process.

### CROSS-REFERENCE TO RELATED APPLICATIONS

This application claims priority to and the benefit of Chinese Patent Application Serial No. 202320204779.3, filed on Feb. 9, 2023. This application also claims priority to and the benefit of Chinese Patent Application Serial No. 202310108937.X, also filed on Feb. 9, 2023. The contents of these applications are incorporated herein by reference in their entirety.

### TECHNICAL FIELD

This application relates to electrical interconnection systems, such as those including electrical connectors, used to interconnect electronic assemblies.

### BACKGROUND

Electrical connectors are used in many electronic systems. It is easier and more cost effective to manufacture a system as several printed circuit boards (PCB), which may be joined together with electrical connectors. Having separable connectors enables components of the electronic system manufactured by different manufacturers to be readily assembled. Separable connectors also enable components to be readily replaced after the system is assembled, either to replace defective components or to upgrade the system with higher performance components.

Computers, for example, are often manufactured with connectors that serve as sockets for memory cards. A memory card may contain one or multiple memory chips and may be inserted into a socket to increase the available memory in the computer. Memory cards have standardized electrical and mechanical interfaces, so as do the memory sockets. Many memory cards, for example, are designed according to a DDR standard, such as DDR4 or DDR5.

### BRIEF SUMMARY

Aspects of the present disclosure relate to card edge connector high density electronic system.

Some embodiments relate to an electrical connector. The electrical connector may include a housing having a plurality of slots extending in parallel to each other, each of the plurality of slots configured for receiving a respective mating component; and a plurality of latches pivotably connected to the housing so as to pivot between a locked position and an unlocked position. Each of the plurality of slots may have a latch of the plurality of latches disposed at an end of the slot and configured for retaining the mating component in the slot when the latch is in the locked positon and releasing the mating component from the slot when the latch is in the unlocked position.

Optionally, each of the plurality of slots is configured for receiving a DDR card; and adjacent slots of the plurality of slots have a center-to-center distance between 4.2 mm and 5.4 mm.

Optionally, the housing comprises a body extending in a longitudinal direction and a tower disposed at an end of the body and extending from the body in a vertical direction perpendicular to the longitudinal direction; the plurality of slots extend from the body into the tower; and the plurality of latches are pivotably connected to the tower.

Optionally, the electrical connector may include a reinforcing member disposed at an end of the tower, wherein the reinforcing member comprises a U-shaped body surrounding ends of the plurality of slots.

Optionally, the reinforcing member comprises an opening; and the plurality of slots extend into the opening of the reinforcing member.

Optionally, the tower comprises a plurality of chambers corresponding to the plurality of latches, respectively, and a plurality of first projections each extending into a respective chamber of the plurality of chambers; and each of the plurality of latches comprises a second projection configured to engage a respective first projection when the latch is in the locked position.

Optionally, the housing comprises a plurality of sidewalls at an end and a plurality of recesses between adjacent sidewalls of the plurality of sidewalls; and each of the plurality of latches is disposed in a recess of the plurality of recesses and povitably connected to respective sidewalls.

Some embodiments relate to an electrical connector. The electrical connector may include a housing having a plurality of slots extending in parallel to each other, each of the plurality of slots configured for receiving a mating component; and a plurality of conductive elements held by the housing, each of the plurality of conductive elements comprising a mating end having a mating contact portion curving into a slot of the plurality of slots, a mounting end opposite the mating end, and an intermediate portion joining the mating end and the mounting end. For each of the plurality of conductive elements: the mounting end may be narrower than the intermediate portion and disposed such that the intermediate portion extends beyond opposite sides of the mounting end; and the mounting end may comprise a flat surface configured for a solder ball attached thereto.

Optionally, the electrical connector may include a plurality of solder balls attached to respective mounting ends of the plurality of conductive elements.

Optionally, for each of the plurality of conductive elements: the flat surface is narrower than a diameter of the solder ball.

Optionally, each of the plurality of conductive elements comprises a pair of cuts disposed on opposite sides of the mounting end.

Optionally, each of the plurality of slots is configured for receiving a DDR card; and adjacent slots of the plurality of slots have a center-to-center distance between 4.2 mm and 5.4 mm.

Optionally, the housing comprises a first wall between adjacent slots of the plurality of slots; the first wall has a thickness between 2.5 mm and 3 mm in a direction perpendicular to a direction in which the plurality of slots extend; the housing comprises a second wall disposed on an outermost side of the plurality of slots; and the outer wall has a thickness between 1.7 mm and 1.75 mm.

Optionally, the electrical connector may include at least one latch pivotably connected to the housing so as to pivot between a locked position and an unlocked position.

Some embodiments relate to an electronic system. The electronic system may include a first printed circuit board having a plurality of contact pads; and a plurality of electrical connectors mounted on the first printed circuit board. Each of the plurality of electrical connectors may include a plurality of conductive elements electrically connected with respective contact pads of the plurality of contact pads of the first printed circuit, and a plurality of slots extending in parallel to each other, each of the plurality of slots configured for receiving a second printed circuit board.

Optionally, a center-to-center distance between two adjacent slots of adjacent electrical connectors is larger than a center-to-center distance between two adjacent slots of the same connectors, such that pitch of the second printed boards is not uniform.

Optionally, the center-to-center distance between the two adjacent slots of the same connectors is between 4.2 mm and 5.4 mm; and the center-to-center distance between the two adjacent slots of adjacent electrical connectors is between 5 mm and 6 mm.

Optionally, the plurality of contact pads are circular contact pads.

Optionally, for each of the plurality of electrical connectors: contact pads in two adjacent rows have a center-to-center distance between 0.9 mm and 1.0 mm.

Optionally, the first printed circuit board has a length in a transverse direction perpendicular to a longitudinal direction in which the plurality of slots extend; the plurality of electrical connectors comprises at least twenty-four electrical connectors disposed within the footprint of the first printed circuit board; the electronic system further comprises two processors disposed within the footprint of the first printed circuit board; and the length of the first printed circuit board is between 480 mm and 490 mm.

Some embodiments relate to a card edge connector. The card edge connector may comprise an insulating housing having a plurality of slots elongating in a longitudinal direction and a plurality of latches connected to the insulating housing. The plurality of slots may be arranged side-by-side in a transverse direction perpendicular to the longitudinal direction. The plurality of slots may be configured for receiving a plurality of add-in card. Each of the plurality of slots may have a respective latch for locking a respective add-in card received by the slot.

Optionally, a plurality of latch mounting recesses may be disposed at an end of the insulating housing. The plurality of latches may be correspondingly connected to the plurality of latch mounting recesses. Each of the plurality of latches may be provided with pivots on two sides, and each of the plurality of latch mounting recesses may be provided with pivot holes in sidewalls thereof. The pivots of each of the plurality of latches may be pivotably connected to pivot holes of a respective latch mounting recess.

Optionally, two pivot holes in a sidewall between adjacent latch mounting recesses of the plurality of latch mounting recesses may be in communication with each other.

Optionally, the insulating housing may include a mating face and a mounting face arranged oppositely in a vertical direction perpendicular to the transverse direction and the longitudinal direction. The plurality of slots may be recessed from the mating face. The card edge connector may further include a plurality of conductive elements held by the insulating housing. Each of the plurality of conductive elements may comprise a mating end having a mating contact portion curving into a corresponding slot and a mounting end opposite the mating end. The mounting end may extend beyond the insulating housing via the mounting face. The insulating housing may further be provided with a passageway that extends from at least a part of the pivot holes to the mounting face in the vertical direction.

Optionally, the passageway may be disposed outside a respective latch mounting recess.

Optionally, each of the plurality of latch mounting recesses may be provided with passageways on two sides thereof.

Optionally, the passageway may include a groove recessed inwardly from an outer side surface of the insulating housing.

Optionally, an outermost pivot hole of the pivot holes in the transverse direction may extend through to the bottom of the groove in the transverse direction.

Optionally, the passageway may include a slit inside the insulating housing, and the slit may communicate to two pivot holes between adjacent latch mounting recesses of the plurality of latch mounting recesses in the transverse direction.

Optionally, a dimension of the passageway may be equal to an aperture of a respective pivot hole in the longitudinal direction.

Optionally, the insulating housing may comprise a body extending in the longitudinal direction and two towers. The two towers may be connected to two ends of the body respectively and protrude from the body in a vertical direction perpendicular to the transverse direction and the longitudinal direction. The plurality of slots may extend from the body into the two towers, and the plurality of latches may be pivotably connected to the two towers.

Optionally, each of the two towers may be provided with a reinforcing member having an opening, and corresponding ends of the plurality of slots may extend into the opening.

Optionally, the reinforcing member may be C-shaped and embrace the corresponding ends of the plurality of slots.

Optionally, each of the plurality of latches may include a pivoting end pivotably connected to the insulating housing, a locking end for locking a respective add-in card, and a connecting portion joining the pivoting end and the locking end. Locking ends of latches of each of the two towers may be directly adjacent to each other in the transverse direction, and the overall dimension of the locking ends may match the dimension of the tower in the transverse direction.

Optionally, each of the two towers may include a plurality of recessed chambers that are in one-to-one correspondence with the plurality of slots. Each of the plurality of recessed chambers may be provided with a first projection on a sidewall thereof, and a connecting portion of each of the plurality of latches may be provided with a lug having a second projection. The second projection may be engaged to the first projection when a corresponding latch is locked to the insulating housing.

Optionally, each of the plurality of recessed chambers may extend to a corresponding slot in the longitudinal direction.

Optionally, a center-to-center distance between adjacent slots of the plurality of slots may be between 4.2 mm and 5.4 mm.

Some embodiments relate to a card edge connector. The card edge connector may comprise an insulating housing, a plurality of conductive elements held by the insulating housing and a plurality of solder balls. An insulating housing may have a plurality of slots elongating in a longitudinal direction, and the plurality of slots may be arranged side-by-side in a transverse direction perpendicular to the longitudinal direction. Each of the plurality of conductive elements may comprise a mating contact portion curving into a corresponding slot, a mounting end extending out of the insulating housing, and an intermediate portion joining the mating contact portion and the mounting end. Each of the plurality of solder balls may be attached to the mounting end of a respective conductive element of the plurality of conductive elements.

Optionally, for each of the plurality of conductive elements: the mounting end may be narrower than the intermediate portion in the longitudinal direction, such that the intermediate portion extends beyond opposite sides of the mounting end in the longitudinal direction. The mounting end may comprise a flat surface attached with a respective solder ball of the plurality of solder balls. The flat surface may be narrower in the longitudinal direction than a diameter of the respective solder ball.

Optionally, the intermediate portion of each of the plurality of conductive elements may have a dimension greater than the diameter of the respective solder ball in the longitudinal direction.

Optionally, for each of the plurality of conductive elements, the mounting end may be centrally aligned with the intermediate portion in the longitudinal direction.

Optionally, each of the plurality of conductive elements may comprise cuts disposed on the opposite sides of the mounting end in the longitudinal direction.

Optionally, the mounting end of each of the plurality of conductive elements may comprise an extension extending in the transverse direction, and the extension may comprise the flat surface.

Optionally, the extension may not extend beyond an outer side surface of the insulating housing in the transverse direction.

Optionally, the mounting end of each of the plurality of conductive elements may extend in a vertical direction perpendicular to the transverse direction and the longitudinal direction, and the flat surface may be on an end surface of the mounting end.

Optionally, the plurality of conductive elements may comprise a first plurality of conductive elements arranged in first rows in the longitudinal direction and a second plurality of conductive elements arranged in second rows in the longitudinal direction. Each of the plurality of slots may have a first side and a second side opposed in the transverse direction. The first rows may be on first sides of the plurality of slots, and the second rows may be on second sides of the plurality of slots.

Optionally, the insulating housing may include a mating face and a mounting face arranged oppositely in a vertical direction perpendicular to the transverse direction and the longitudinal direction. The plurality of slots may be recessed from the mating face. The mounting end of each of the plurality of conductive elements may extend beyond the insulating housing via the mounting face.

Optionally, a center-to-center distance between adjacent slots of the plurality of slots may be between 4.2 mm and 5.4 mm.

Optionally, the insulating housing may include an inner wall between adjacent slots of the plurality of slots, and the thickness of the inner wall may be between 2.5 mm and 3 mm.

Optionally, the insulating housing may include an outer wall disposed on an outermost side of the plurality of slots in the transverse direction, and the thickness of the outer wall may be between 1.7 mm and 1.75 mm.

Some embodiments relate to an electronic system. The electronic system may comprise a first printed circuit board having a plurality of contact pads, and a plurality of card edge connectors installed to the first printed circuit board. Each of the plurality of card edge connectors may be configured for receiving a plurality of second printed circuit boards. The plurality of card edge connectors may comprise a plurality of conductive elements that are electrically connected with the plurality of contact pads in one-to-one correspondence.

Optionally, the first printed circuit board may have a footprint, and the plurality of card edge connectors and a processor socket may be within the footprint.

Optionally, the dimension of the footprint in a transverse direction may be between 480 mm and 490 mm. There may be two processor sockets and twenty-four card edge connectors, and each of the twenty-four card edge connectors may be configured for receiving two second printed circuit boards.

Optionally, adjacent second printed circuit boards of the plurality of second printed circuit boards of each of the plurality of card edge connectors may have a center-to-center distance between 4.2 mm and 5.4 mm.

Optionally, adjacent second printed circuit boards of adjacent card edge connectors of the plurality of card edge connectors may have a center-to-center distance between 5 mm and 6 mm.

Optionally, the plurality of second printed circuit boards may be perpendicular to the first printed circuit board. The plurality of second printed circuit boards may extend in a longitudinal direction parallel to the first printed circuit board. The plurality of second printed circuit boards may be disposed side by side in a transverse direction perpendicular to the longitudinal direction.

Optionally, each of the plurality of contact pads may be circular in shape.

Optionally, for each of the plurality of card edge connectors, a portion of adjacent contact pads may have a minimum center-to-center distance between 0.9 mm and 1.0 mm.

These techniques may be used alone or in any suitable combination. The foregoing summary is provided by way of illustration and is not intended to be limiting.

### BRIEF DESCRIPTION OF DRAWINGS

The accompanying drawings may not be drawn to scale. In the drawings, each identical or nearly identical component that is illustrated in various figures may be represented by a like numeral. For purposes of clarity, not every component may be labeled in every drawing. In the drawings:

FIG. 1 is a perspective view of an electronic system, showing an electrical connector mounted on a printed circuit board, according to some embodiments;

FIG. 2A is a side view of an electronic system, showing multiple electrical connectors mounted on a printed circuit board, according to some embodiments;

FIG. 2B is an enlarged side view of a portion of the electronic system of FIG. 2A;

FIG. 3 is a perspective view of an electrical connector and components inserted therein, showing latches in a locked position, according to some embodiment;

FIG. 4 is a perspective view of the electrical connector and components of FIG. 3, showing latches in an unlocked position;

FIG. 5 is a perspective view of the electrical connector of FIG. 3;

FIG. 6 is an exploded perspective view of the electrical connector of FIG. 5;

FIG. 7 is an enlarged partial perspective view of the electrical connector of FIG. 5;

FIG. 8 is another enlarged partial perspective view of the electrical connector of FIG. 5;

FIG. 9 is a cross-sectional partial perspective view of the electrical connector of FIG. 5, showing the latches in the locked position;

FIG. 10 is a perspective view of an insulating housing of the electrical connector of FIG. 5;

FIG. 11 is an enlarged partial perspective view of the insulating housing of FIG. 9;

FIG. 12 is another enlarged partial perspective view of the insulating housing of FIG. 9;

FIG. 13 is another enlarged partial perspective view of the insulating housing of FIG. 9;

FIG. 14 is a perspective view of a latch of the electrical connector of FIG. 5;

FIG. 15 is another perspective view of the latch of FIG. 14;

FIG. 16 is a perspective view of a reinforcing member of the electrical connector of FIG. 5;

FIG. 17 is a perspective view of conductive elements with solder balls attached thereon of the electrical connector of FIG. 5;

FIG. 18 is an elevation view of the conductive elements with solder balls of FIG. 17; and

FIG. 19 is a schematic diagram illustrating conductive elements connected to contact pads via solder balls, according to some embodiments.

The above accompanying drawings include the following reference signs:
100, card edge connector; 200, insulating housing; 201, mating face; 202, mounting face; 203, outer side surface; 210, slot; 211, first slot; 212, second slot; 230, latch mounting recess; 231, pivot hole; 231a, first pivot hole; 231b, second pivot hole; 232, abutting portion; 240, passageway; 241, groove; 242, slit; 250, body; 260, tower; 261, recessed chamber; 262, first projection; 270, inner wall; 280, outer wall; 290, groove; 291, first positioning portion; 292, second positioning portion; 293, third positioning portion; 294, fourth positioning portion; 300, latch; 301, first latch; 302, second latch; 310, pivot; 311, protrusion; 312, guide surface; 320, pivoting end; 330, locking end; 331, locking rib; 340, connecting portion; 341, lug; 342, second projection; 350, heat dissipation hole; 400, conductive element; 401, first row; 402, second row; 410, mating contact portion; 420, mounting end; 421, flat surface; 430, intermediate portion; 440, cut; 500, reinforcing member; 501, opening; 510, reinforcing body 521, first hook; 522, second hook; 530, chamfer; 541, first body extension; 542, second body extension; 551, first hook extension; 552, second hook extension; 600, solder ball; 700, board lock; 910, first printed circuit board; 911, footprint; 912, processor socket; 913, contact pad; 914, conductive trace; 920, add-in card; 921, first add-in card; 922, second add-in card; 923, notch; 930, processor.

### DETAILED DESCRIPTION

The inventors have recognized and appreciated connector design techniques for high density, high speed, and high performance electronic systems. An electronic system may be assembled from multiple components inserted into a support structure such as a rack that has a standardized width and depth that limits the space available for connectors. Existing connectors cannot satisfy the increasing need of having more components in one rack and also meet signal integrity requirements in connectors designed to operate at higher speed. The inventors have recognized and appreciated designs for electrical connectors that may be used in an electronic system to receive more mating components (e.g., add-in cards) in a constrained space while maintaining and/or improving signal integrity at high speed. The techniques described herein can also increase the tolerance of errors in the manufacturing process (e.g., the range of coplanarity between the mounting ends of a connector).

According to aspects of the present application, an electrical connector may have a housing that has multiple slots. Each slot may receive a mating component, such as an electronic card. The connector may have multiple narrow latches, each configured to lock a card in a respective slot. The housing may have narrower walls to reduce its overall size and one or more reinforcing members configured to enhance the mechanical strength of the housing. Moreover, a shared wall between two parallel slots in the connector may have a thickness that is less than twice the thickness of an exterior wall between a slot and the exterior of the connector. Conductive elements may be disposed on one or more sides of each slot. The conductive elements may have mounting tails configured for solder ball attachment such that the conductive elements of adjacent slots may be disposed closer. The mounting ends of the conductive elements are also configured such that a smaller solder area is needed on a circuit board (e.g., a motherboard) on which the connector is mounted. These configurations improve signal integrity at high speed. Further, these configurations may increase the tolerance of errors in the manufacturing process. For example, while existing surface mount tails may tolerate a maximum of 0.1 mm variation in coplanarity, the mounting ends described herein may tolerate 0.2 mm variation in coplanarity. The ability to accommodate for greater variation in coplanarity may enable a larger connector housing with multiple card slots, because larger housings are more likely to exhibit greater variation in coplanarity across the housing.

A connector satisfying the mechanical requirements of the DDR specification at the performance required for DDR5 and beyond is used as an example of a connector in which these techniques have been applied. The connector may have multiple slots, each of which can receive a card.

Conductive elements disposed on opposite sides of each slot may connect a card inserted therein to a circuit board on which the connector is mounted. Each conductive element may have a mating end having a mating contact portion curving into a respective slot, a mounting end opposite the mating end, and an intermediate portion joining the mating end and the mounting end. The mounting end may have a flat surface configured for solder ball attachment extending in a plane perpendicular to a mating direction in which the card is inserted into the slot.

Each conductive element may have a pair of cuts disposed on opposite sides of the mounting end such that the mounting end is narrower than the intermediate portion. Such mounting ends may enable a solder ball having a diameter greater than a width of the flat surface of the respective mounting end in a direction in which the slot extends (e.g., a longitudinal direction) to be attached to the mounting end. For example, solder material may fill the pair of cuts during reflow. Integrity of signal transmitted by the connecter may be improved through the configuration of the narrower mounting end with the pair of cuts, attaching a larger solder ball to a flat surface of the narrower mounting end of the conductive element, and/or the combination thereof. Also, conductive elements of adjacent slots may be disposed closer, which may reduce the overall size of the connector. Further, these configurations increase the tolerance of errors in the manufacturing process. For example, while existing surface mount tails may tolerate a maximum of 0.1 mm variation in coplanarity, the mounting ends described herein may tolerate 0.2 mm variation in coplanarity.

The housing of the connector may have a body and one or more towers extending from each end of the body in a vertical direction (e.g., one tower at each end). The connector may have one or more latches pivotably connected to respective towers of the housing such that each latch is movably between a locked position and an unlocked position. For example, each slot may have a pair of latches disposed at opposite ends for retaining the card inserted therein when the latches are in the locked position and releasing the card from the slot when the latches are in the unlocked position. The connector may have reinforcing members disposed at ends of the towers and configured to enhance the mechanical strength of the towers for sustaining the forces that may be applied therein during operation (e.g., inserting and/or removing the card).

A card edge connector and electronic system are described in detail hereinbelow in conjunction with the drawings. A vertical direction Z-Z, a longitudinal direction X-X and a transverse direction Y-Y may be shown in the drawings. The vertical direction Z-Z, the longitudinal direction X-X and the transverse direction Y-Y may be perpendicular to one another. The vertical direction Z-Z may refer to a height direction of the card edge connector, which in this example is a direction from the mounting interface of the connector towards a surface containing slots that receive a mating component. The longitudinal direction X-X may refer to a length direction of the card edge connector. The transverse direction Y-Y may refer to a width direction of the card edge connector, with the connector being elongated in the length direction and narrower in the width direction than the length direction.

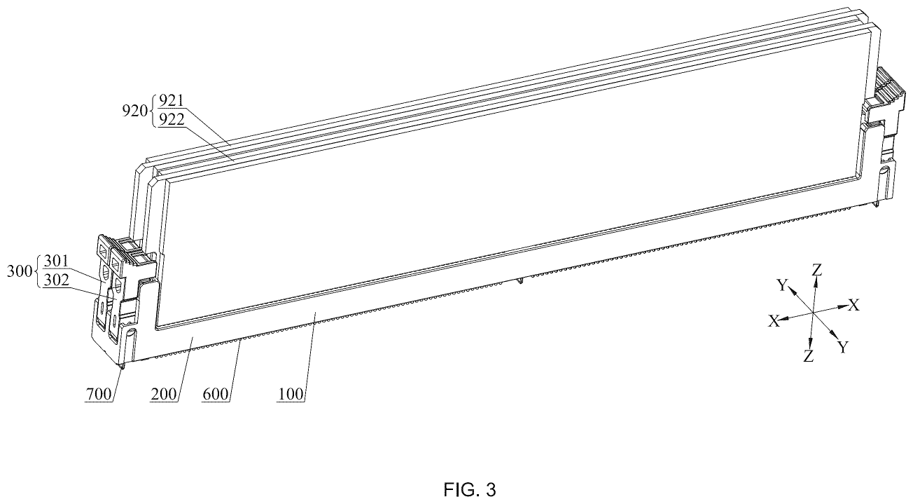

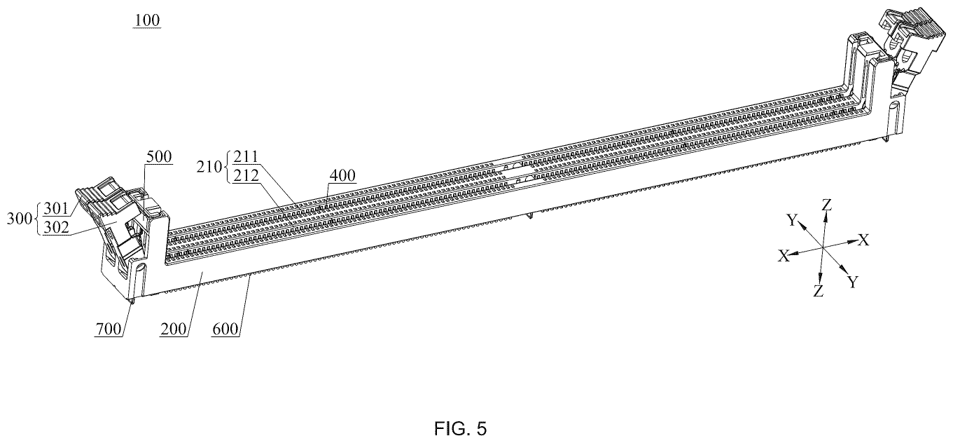

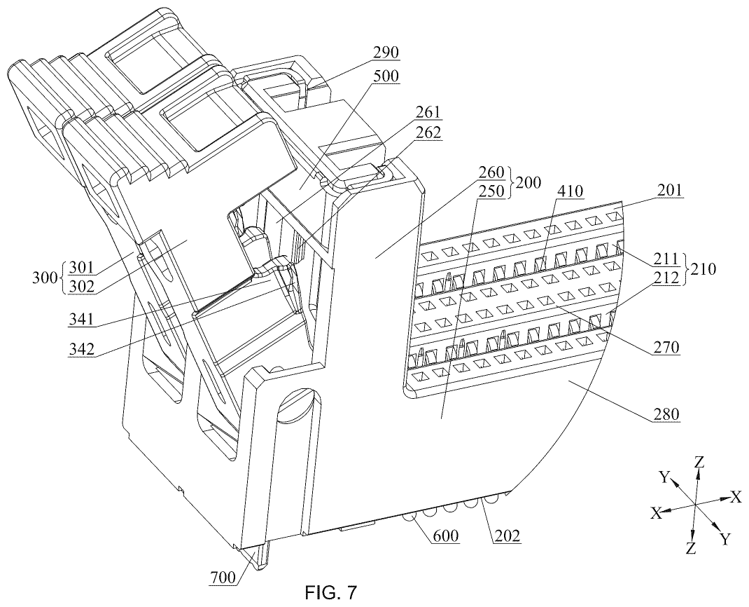

As shown in FIGS. 3-13, the card edge connector 100 may include an insulating housing 200. As shown in FIG. 7, the insulating housing 200 may have an mating face 201 and a mounting face 202. The mating face 201 and the mounting face 202 may be arranged oppositely in the vertical direction Z-Z. Slots 210 may extend from the mating face 201. Exemplarily, the slots 210 may be recessed inwards in the vertical direction Z-Z from the mating face 201. Each slot 210 may be configured to receive a mating component such as a printed circuit board. Add-in card 920 is shown as an example. Specifically, the add-in card 920 may be inserted into slot 210 in the vertical direction Z-Z. The vertical direction Z-Z may be a mating direction of the add-in card 920 with the card edge connector 100. The slot 210 may be used for receiving an edge of the add-in card 920, so as to hold the add-in card 920 to the insulating housing 200. The add-in card 920 may include one or more of a display card, a memory card, a sound card and the like. The insulating housing 200 may be molded of an insulating material, for example, plastic. The insulating housing 200 may be an one-piece member.

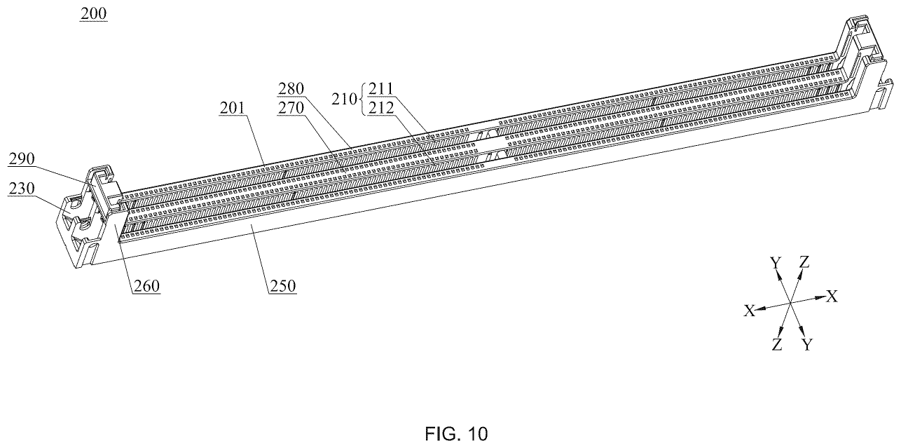

As shown in FIGS. 10-13, the insulating housing 200 may be in an elongated strip shape. The insulating housing 200 may extend in the longitudinal direction X-X. The slots 210 each may be in an elongate shape extending in the longitudinal direction X-X. The number of slots 210 includes the two illustrated in the figures, and may for example be three, four, or more. The slots 210 may be arranged side-by-side in the transverse direction Y-Y. Exemplarily, the insulating housing 200 may include an inner wall 270 and two outer walls 280 spaced apart in the transverse direction Y-Y. In the transverse direction Y-Y, the two outer walls 280 may be disposed on the outermost sides of a plurality of slots 210, and the inner wall 270 may be disposed between adjacent slots 210. The inner wall 270 may be disposed between the outer walls 280 in the transverse direction Y-Y. The intervals between the inner wall 270 and the outer walls 280 may form the slots 210. Any two adjacent inner walls 270, if any, may also form a slot 210. In the embodiments illustrated in the drawing, a first slot 211 may be formed between the inner wall 270 and one outer wall 280, and a second slot 212 may be formed between the inner wall 270 and the other outer wall 280. In embodiments provided with three slots 210, there may be two inner walls 270, and a third slot may be formed between the two inner walls 270.

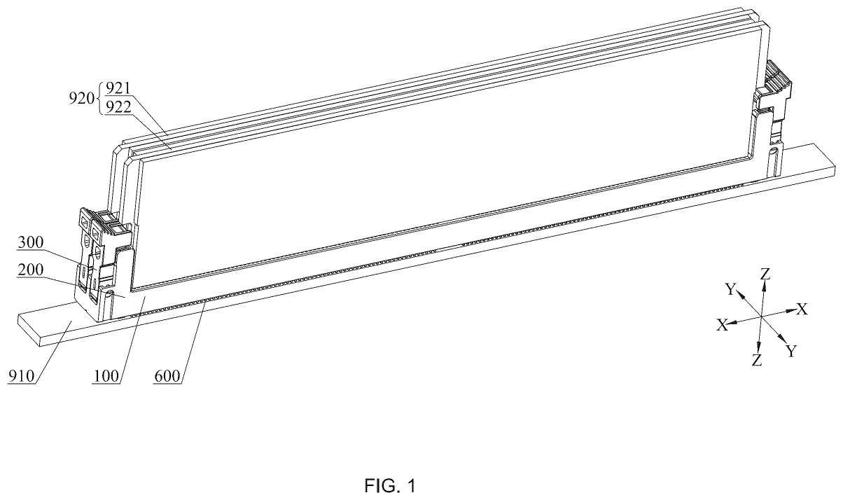

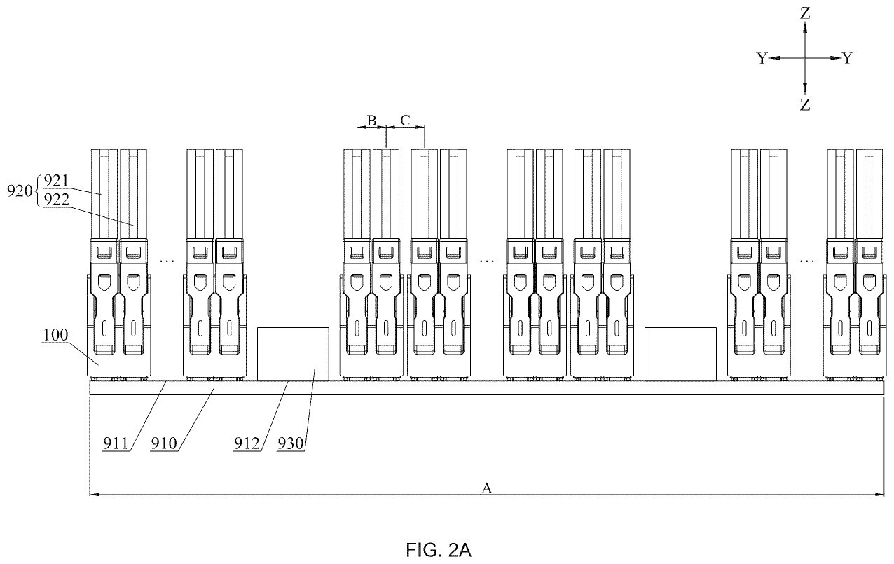

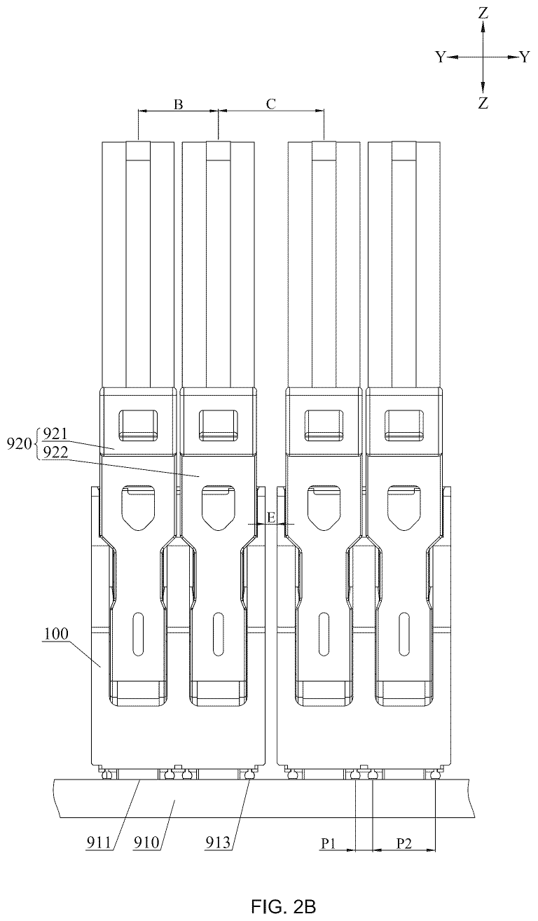

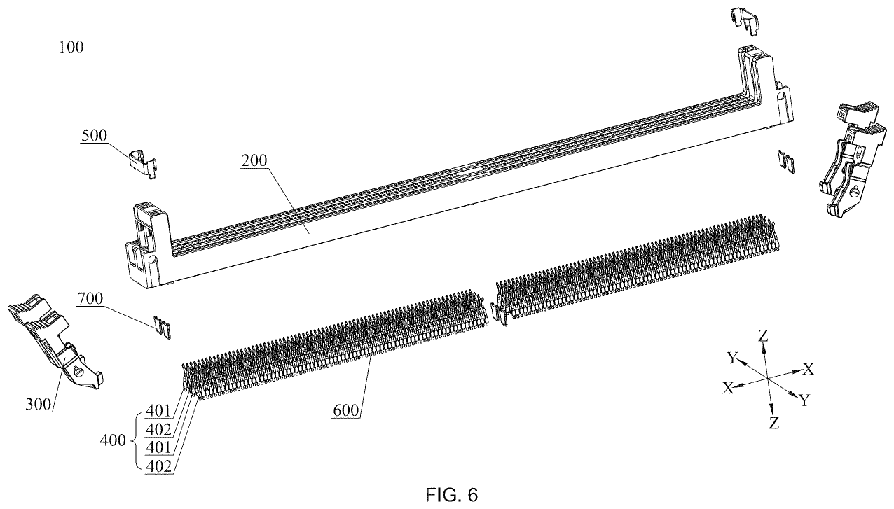

The plurality of slots 210 may each be used to receive a respective add-in card 920. The plurality of slots 210 may have same or different configurations. The add-in cards 920 inserted into the plurality of slots 210 may have same or different configurations. Taking the embodiments illustrated in the drawing as examples, the slots 210 may include the first slot 211 and the second slot 212. The first slot 211 may be used to receive a first add-in card 921, and the second slot 212 to receive a second add-in card 922. In conjunction with FIG. 1 and FIGS. 2A-2B, as shown, a card edge connector 100 may be mounted to a first printed circuit board 910. The first printed circuit board 910 may be configured to be a motherboard. Exemplarily, the card edge connector 100 may further comprise board locks 700, as shown in FIG. 6. One end of each board lock 700 may be connected to the insulating housing 200 by any suitable means, such as insertion, and the other end of the board lock 700 may be connected to the first printed circuit board 910 by any suitable means, such as insertion. In this way, the card edge connector 100 may be mounted to the first printed circuit board 910 by the board locks 700. The board locks 700 may be made of materials with stronger strength, such as plastics, ceramics, or metal. Optionally, the board locks 700 may be made of metallic materials. Metallic materials have stronger mechanical strength and lower material and processing costs. Optionally, each of the board locks 700 is a sheet metal piece. In this way, the board locks 700 have higher mechanical strength and are simple and less costly to process.

The card edge connector 100 may include a plurality of conductive elements 400. The plurality of conductive elements 400 may be held by the insulating housing 200. The plurality of conductive elements 400 may be arranged in the longitudinal direction X-X and spaced apart from each other in the insulating housing 200, enabling adjacent conductive elements 400 to be electrically insulated from each other. The plurality of conductive elements 400 may be arranged in two rows on two sides of each slot 210. Each row is parallel to the longitudinal direction X-X. Optionally, the two rows of conductive elements 400 may be aligned with each other in the longitudinal direction X-X. Optionally, the two rows of conductive elements 400 are staggered in the longitudinal direction X-X to increase the space between the conductive elements 400 in order to reduce crosstalk. Optionally, two rows of conductive elements 400 have the same construction, but are mirror images of each other. Optionally, the conductive elements 400 may be disposed on only one side of the slot 210, if necessary.

Exemplarily, the plurality of conductive elements 400 may include a first plurality of conductive elements and a second plurality of conductive elements. The first plurality of conductive elements may be arranged in a plurality of first rows 401 in the longitudinal direction X-X. The second plurality of conductive elements may be arranged in a plurality of second rows 402 in the longitudinal direction X-X. The plurality of first rows 401 and the plurality of second rows 402 may be disposed in correspondence with the plurality of slots 210, respectively. The plurality of first rows 401 may be disposed on first sides of the plurality of slots 210 in one-to-one correspondence. The plurality of second rows 402 may be disposed on second sides of the plurality of slots 210 in one-to-one correspondence. The first side and the second side of each slot 210 may be opposite each other in the transverse direction Y-Y. The conductive elements in the plurality of first rows 401 may have the same construction. The conductive elements in the plurality of second rows 402 may have the same construction, and are in mirror images with the conductive elements in the plurality of first rows 401. The conductive elements in the first row 401 and the second row 402 on both sides of each slot 210 may be in electrical contact with adapted conductive elements on the add-in card 920 received by the said slot 210.

Optionally, each conductive element 400 is held in a channel in the insulating housing 200. There may be two rows of channels in the inner wall 270, for holding the conductive elements in one first row 401 and one second row 402, respectively. And there may be one row of channels in each outer wall 280. The two outer walls 280 may be provided with conductive elements arranged in one first row 401 and conductive elements arranged in one second row 402, respectively, while the inner wall 270 is provided with both conductive elements arranged in one first row 401 and conductive elements arranged in one second row 402. The conductive elements in the first row 401 and the second row 402 of each inner wall 270 are electrically insulated from each other. To reduce crosstalk, the conductive elements in the first row 401 and the second row 402 of each inner wall 270 may be staggered in the longitudinal direction X-X, such as by a half of the center-to-center distance between adjacent conductive elements in the same row. The thickness (e.g., the transverse dimension) of the inner wall 270 may be greater than the thickness (e.g., the transverse dimension) of the outer walls 280 to accommodate the two rows of conductive elements.

Exemplarily, the thickness of the inner wall 270 may be approximately between 2.5 mm and 3 mm. Optionally, the thickness of the inner wall 270 may be approximately between 2.7 mm and 2.8 mm. Optionally, the thickness of the inner wall 270 may be approximately 2.75 mm. In this way, the inner wall 270 can be thinner, but may also provide sufficient mounting space for the two rows of conductive elements and ensure that the inner wall 270 has sufficient mechanical strength.

Optionally, the thickness of each outer wall 280 may be greater than a half of the thickness of the inner wall 270 to ensure that the outer wall 280 has sufficient mechanical strength. Exemplarily, the thickness of the outer wall 280 may be approximately between 1.7 mm and 1.75 mm. Optionally, the thickness of the outer wall 280 may be approximately between 1.72 mm and 1.74 mm. Optionally, the thickness of the outer wall 280 may be approximately 1.73 mm.

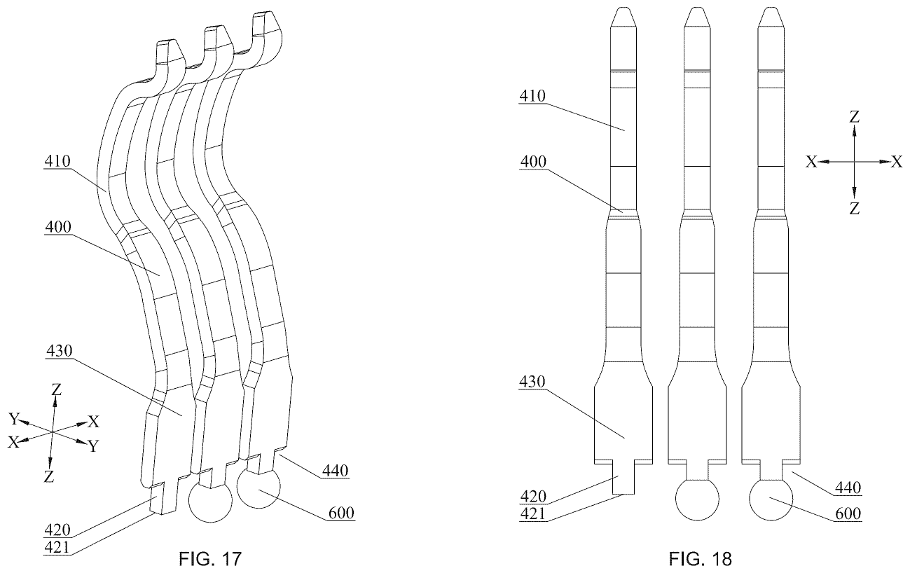

The conductive elements 400 may be made of conductive materials, such as metal. The conductive elements 400 each may be an elongated one-piece member. In conjunction with FIGS. 17-18, as shown, each conductive element 400 may include a mating end having a mating contact portion 410 at one end, a mounting end 420 at the other end, and an intermediate portion 430 connected between the mating contact portion 410 and the mounting end 420, in its extension direction. The mating contact portion 410 may be inside the insulating housing 200. The mating contact portion 410 may be disposed on the side of the slot 210. Optionally, the mating contact portion 410 is bent and protruded into the slot 210. The mating contact portion 410 may be used for electrical connection to the add-in card 920. The add-in card 920 may have a plurality of adapted conductive elements, such as gold fingers. When the add-in card 920 is inserted into the slot 210, the mating contact portions 410 may be in electrical contact with the adapted conductive elements on the add-in card 920, thereby achieving electrical connection. Each mounting end 420 may be beyond the insulating housing 200. Optionally, the mounting ends 420 may extend beyond the insulating housing 200 via the mounting face 202. The mounting ends 420 may be directly or indirectly soldered to contact pads 913 on the first printed circuit board 910 by any suitable means such as, Surface Mounted Technology (SMT) and/or Through-Hole Technology (THT). In this way, the add-in card 920 may be electrically connected to the first printed circuit board 910 via the card edge connector 100.

Exemplarily, the card edge connector 100 may comprise a plurality of latches 300. The plurality of latches 300 may have same or different configurations. The latches 300 may be connected to the insulating housing 200. The latches 300 may be molded from insulating materials, such as plastics, using a molding process. Each latch 300 may be a one-piece member. The latches 300 and the insulating housing 200 may be of the same or different materials. Each slot 210 may have corresponding latches 300 at opposite ends in the longitudinal direction X-X. In this way, the latches 300 may lock the add-in card 920 received by the respective slot 210. In the exemplary embodiment illustrated in the drawing, the latches 300 may comprise first latches 301 and second latches 302. The first slot 211 may correspond to the first latches 301. The first latches 301 may lock a first add-in card 921 received by the first slot 211. The second slot 212 may correspond to the second latches 302. The second latches 302 may lock a second add-in card 922 received by the second slot 212.

Although each slot 210 is provided with latches 300 at both ends in the longitudinal direction X-X in the drawings and the descriptions above, some or all of the slots 210 may be provided with latches 300 only at one end in the longitudinal direction X-X in other embodiments.

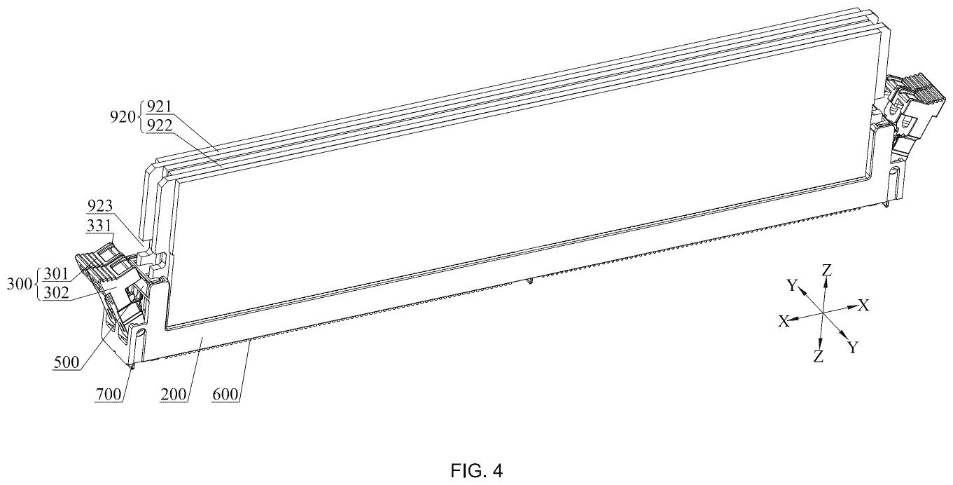

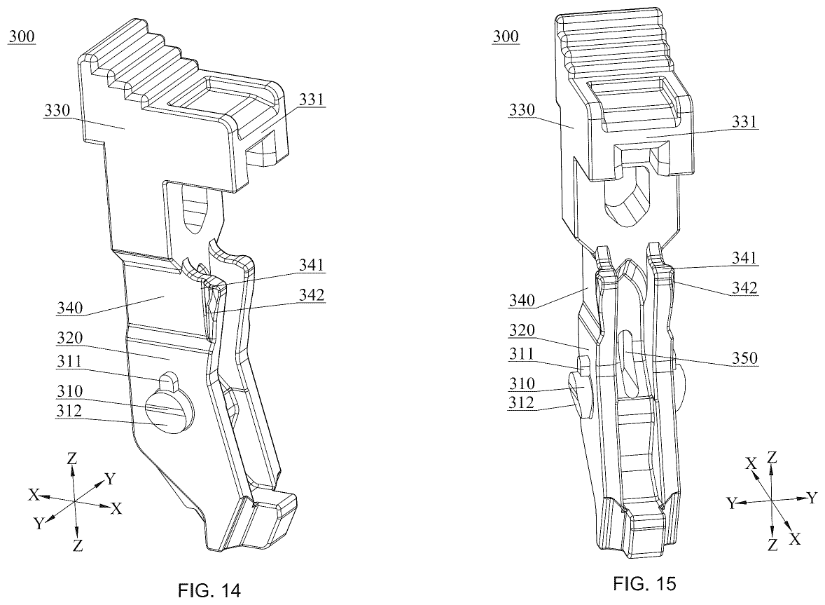

In conjunction with FIGS. 14-15, as shown, each latch 300 may include a pivoting end 320, a locking end 330, and a connecting portion 340. The connecting portion 340 may be connected between the pivoting end 320 and the locking end 330. The pivoting end 320 may be pivotably connected to the insulating housing 200 between an unlocked position and a locked position. The locking end 330 may be used to lock a respective add-in card 920. In FIG. 3, the latches 300 are in the locked position, and the locking ends 330 of the latches 300 may be disposed in the insulating housing 200. Locking ribs 331 at the locking ends 330 may be inserted into notches 923 in the side portions of the corresponding add-in cards 920. As a result, the latches 300 may have the add-in cards 920 locked to the card edge connector 100. The latches 300 are in the unlocked position in FIG. 4, and the locking ribs 331 at the locking ends 330 may exit the notches 923 in the side portions of the corresponding add-in cards 920. The add-in cards 920 can be separated from the insulating housing 200. In this way, the add-in cards 920 can be inserted into the slot 210 or removed from the slot 210.

Exemplarily, a plurality of latch mounting recesses 230 may be provided at the ends of the insulating housing 200. The plurality of latches 300 may be correspondingly connected to the respective latch mounting recesses 230. In addition, the latch mounting recesses 230 may be configured to limit the corresponding latches 300, so that the risks for latches 300 to accidentally move out of intended positions are reduced. In the transverse direction Y-Y, the dimension of the latch mounting recesses 230 may be adapted to the dimension of the pivoting ends 320. As a result, the latch mounting recesses 230 may reduce the risks for the latches 300 to sway in the transverse direction Y-Y.

Exemplarily, each latch 300 may be provided with pivots 310 on two sides opposed in the transverse direction Y-Y. Each latch mounting recess 230 may be provided with opposite pivot holes 231 on two sides in the transverse direction Y-Y. Each pivot 310 may be pivotably connected to the pivot hole 231 of the respective latch mounting recess 230. As shown in FIGS. 14-15, a lower portion of each pivot 310 may be provided with a guide surface 312 that allows the pivot 310 to be inserted downwardly into the corresponding pivot hole 231. The direction in which the pivot 310 is mounted into the corresponding pivot hole 231 is substantially the same as the mating direction in which the add-in card 920 is inserted into the corresponding slot 210. With this configuration, the latches 300 can be easily mounted onto the insulating housing 200 and have a simple structure and low manufacturing costs.

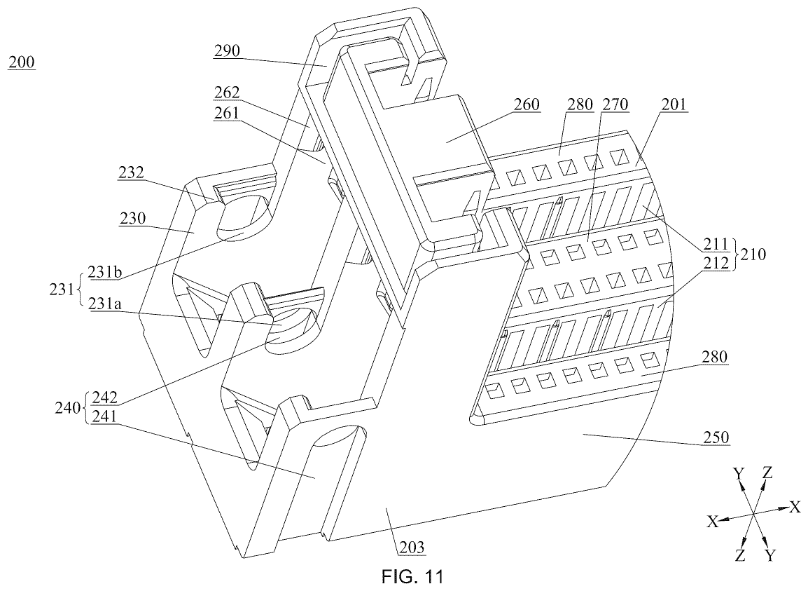

Exemplarily, as shown in FIGS. 14-15, each pivot 310 may be provided with a protrusion 311. The protrusion 311 may protrude substantially upwardly from a peripheral surface of the corresponding pivot 310. The protruding direction of the protrusion 311 may be opposite to the mating direction of the add-in card 920 inserted into the corresponding slot 210. When the latch 300 is pivoted to the unlocked position, the protrusion 311 may abut against a sidewall of the latch mounting recess 230. For example, when the latch 300 is in the unlocked position, the protrusion 311 may abut against an abutting portion 232 in the latch mounting recess 230, as shown in FIGS. 11-14. The abutting portion 232 may be adjacent to the pivot hole 231. When the latch 300 is in the locked position, it may abut against the insulating housing 200 toward the center of the insulating housing 200 in the longitudinal direction X-X. In this way, the latch 300 can be pivotable between the locked position and the unlocked position.

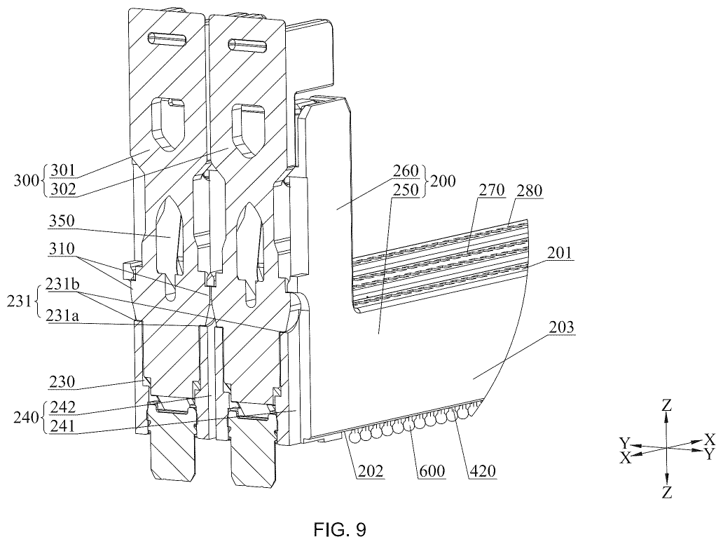

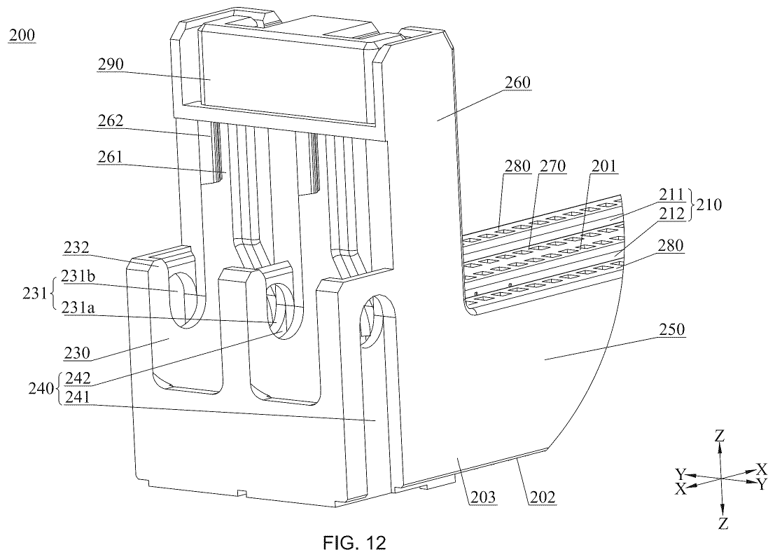

Exemplarily, two pivot holes 231 in the sidewall between adjacent latch mounting recesses 230 of the plurality of latch mounting recesses 230 may be in communication with each other. The pivot holes 231 at in-between position may be referred to as first pivot holes 231a, and the pivot holes 231 on the outermost side may be referred to as second pivot holes 231b, as shown in FIGS. 9 and 12. The aforesaid sidewall is substantially aligned with the inner wall 270 between the two slots 210 in the transverse direction Y-Y. As previously described, the thickness (e.g., transverse dimension) of the inner wall 270 may be smaller than double of the thickness (e.g., transverse dimension) of the outer wall 280. The two first pivot holes 231a in the said sidewall may be connected to each other, e.g., the two first pivot holes 231a can be regarded as a through-hole, so as to have a sufficient depth (transverse dimension) to receive the pivots of the first latch 301 and the second latch 302 with sufficient length, which can improve the connection stability of the first latch 301 and the second latch 302 with the insulating housing 200. And it is also possible to make the pivots 310 of the first latch 301 and the second latch 302 to space apart with a certain gap in the through-hole, to prevent from frictional resistance during rotation. Moreover, such first pivot holes 231a can also be easy to be machined and allow a greater machining tolerance, so that the machining costs of the insulating housing 200 can be lower. Optionally, the first pivot holes 231a may all be blind holes. In the case where blind holes are used, end surfaces of the pivots 310 perpendicular to a pivot axis may come into contact with the bottom of the blind holes due to machining tolerance, resulting in increased resistance when the latches 300 are pivoted. However, in the embodiment where the two first pivot holes 231a communicated to form a single through-hole, this problem can be largely avoided.

Exemplarily, as shown in FIG. 9 and FIGS. 11-13, the insulating housing 200 may further be provided with passageways 240 that extend from at least a part of the pivot holes 231 to the mounting face 202 in a vertical direction Z-Z. In the illustrated embodiment, there is a passageway 240 that extends through from the first pivot holes 231a to the mounting face 202, which may be referred to as a slit 242 hereinafter, and additionally there is a passageway 240 that extends through from the second pivot hole 231b to the mounting face 202, which may be referred to as a groove 241 hereinafter. In other embodiments not shown, only a part of the pivot holes 231 may have corresponding passageways 240. By disposing the passageways 240, the pivot holes 231 can be easily processed during the injection molding of the insulating housing 200, which facilitates preparation of moulds.

Exemplarily, in the longitudinal direction X-X, the passageways 240 are spaced apart from the slots 210 and a longitudinal end surface of the insulating housing 200. Exemplarily, each passageway 240 has a longitudinal dimension that is not greater or slightly greater than the aperture of the corresponding pivot hole. Optionally, the longitudinal dimension of the passageway 240 is equal to the aperture of the corresponding pivot hole 231. The mechanical strength of the insulating housing 200 may be affected if the dimension of the passageways 240 is too large, while the processing difficulty may be enhanced if the dimension of the passageways 240 is too small. Optionally, the passageways 240 may extend in the longitudinal direction X-X to the positions where the ends of the slots 210 are, and/or to the longitudinal end surface (e.g., an outer surface perpendicular to the longitudinal direction X-X) of the insulating housing 200.

In the transverse direction Y-Y, each passageway 240 may be connected to the corresponding latch mounting recess 230. For example, the passageways 240 may be recessed from the side surfaces of the latch mounting recesses 230 in the transverse direction Y-Y. However, this may affect the limit of the latch mounting recesses 230 to the latches 300 in the transverse direction Y-Y. Exemplarily, the passageways 240 may be disposed outside the latch mounting recess 230 in the transverse direction Y-Y. The passageways 240 may be spaced apart from the latch mounting recesses 230 in the transverse direction Y-Y. Thus, the stability of the latches 300 may be unaffected. Exemplarily, each latch mounting recess 230 may be provided with passageways 240 on two opposed sides in the transverse direction Y-Y. With this configuration, the pivot holes 231 in two opposed sidewalls of the latch mounting recess 230 in the transverse direction Y-Y are easy to process, and the insulating housing 200 is inexpensive to manufacture. Only one passageway 240 may be disposed in the sidewall between the two latch mounting recesses 230.

Exemplarily, the passageway 240 may include a groove 241 recessed inwardly from the outer side surface 203 of the insulating housing 200 in the transverse direction Y-Y, as shown in FIGS. 9 and 11-13. The groove 241 may extend from the second pivot hole 231b to the mounting face 202. Exemplarily, the pivot hole 231 outermost in the transverse direction Y-Y, e.g., the second pivot hole 231b, may extend through to the bottom of the groove 241 in the transverse direction Y-Y. This passageway 240 in the form of the groove 241 is easy to process. Moreover, the groove 241 may also accommodate the end of the pivot 310, so that the pivot 310 can be appropriately longer to have enhanced mechanical strength.

Exemplarily, the passageway 240 may include a slit 242 inside the insulating housing 200. The slit 242 may extend in the transverse direction Y-Y from the pivot holes 231 at the in-between position (e.g., the first pivot holes 231a) to the mounting face 202. In the case where the two first pivot holes 231a between the two latch mounting recesses 230 connected to each other to form a through-hole, the slit 242 may extend to the sidewall of the through-hole. The two first pivot holes 231a between the two latch mounting recesses 230 may share one slit 242. With this configuration, the mechanical strength of the insulating housing 200 between the two latch mounting recesses 230 can be ensured.

The card edge connector 100 provided in the embodiments of the present disclosure may receive a plurality of add-in cards 920 by being provided with a plurality of slots 210. Adjacent slots 210 of the card edge connector 100 may share the same wall (e.g., the inner wall 270). The inventors have recognized and appreciated design techniques for connectors to connect multiple components to a board with reduced space while maintaining and/or improving mechanical strength and signal integrity. For example, more card edge connectors 100 may be mounted to the motherboard so that a larger number of add-in cards 920 may be connected onto the limited space of the support structure, thereby improving the performance of the electronic system. Further, since each slot 210 has corresponding latches 300, the plurality of add-in cards 920 inserted into the slots 210 can be stably secured to the insulating housing 200, and the performance of the card edge connector 100 is more stable.

As shown in FIG. 2A, the first printed circuit board 910 may have a footprint 911. A plurality of card edge connectors 100 may be arranged within the footprint 911. Thus, a greater number of second printed circuit boards, such as add-in cards 920, may be electrically connected within the footprint 911. The footprint 911 may also be provided with processor sockets 912. The electronic system may also comprise processors 930. The processors 930 may be mounted to the processor sockets 912. With this configuration, the electronic system is more abundant in performance and the user experience is better.

Exemplarily, as shown in FIG. 2A, the dimension A of the footprint 911 in the transverse direction Y-Y may be approximately between 480 mm and 490 mm. Optionally, the dimension A may be approximately between 481 mm and 484 mm. The number of processor sockets 912 may be two. Each processor socket 912 may be used to mount one processor 930. The number of card edge connectors 100 may be twenty-four. Each card edge connector 100 may be connected with two add-in cards 920. The card edge connectors 100 and the processors 930 may be arranged in any way in the transverse direction Y-Y. In the illustrated example, the two processors 930 may each have eight card edge connectors 100 lined up on the outer side in the transverse direction Y-Y. Sixteen card edge connectors 100 may be lined up between the two processors 930 in the transverse direction Y-Y. The connectors described herein enables the system to be denser. With this configuration, the electronic system can provide more functions and/or storages with a same area of a footprint.

Exemplarily, as shown in FIG. 2B, a center-to-center distance B between adjacent second printed circuit boards in the add-in cards 920 inserted into each card edge connector 100 may be approximately between 4.2 mm and 5.4 mm. Optionally, the center-to-center distance B may be approximately between 4.2 mm and 5 mm. Optionally, the dimension B may be approximately between 4.2 mm and 4.3 mm. With this configuration, the card edge connector 100 has a more compact structure. Moreover, the second printed circuit boards inserted into each card edge connector 100 may have gaps in-between. The card edge connector 100 and the second printed circuit boards generate heat during operation, and the gaps may facilitate ventilation to dissipate heat. Further, the gaps may facilitate mounting and removal of the card edge connector 100.

Exemplarily, a center-to-center distance between adjacent slots 210 of each card edge connector 100 may be approximately between 4.2 mm and 5.4 mm. Optionally, the center-to-center distance may be approximately between 4.2 mm and 5 mm. Optionally, the center-to-center distance may be approximately between 4.2 mm and 4.3 mm. The center-to-center distance between the slots 210 may be related to and/or directly determine, the center-to-center distance B between the add-in cards 920. With this configuration, the card edge connector 100 has a more compact structure. Moreover, the second printed circuit boards within each card edge connector 100 may have gaps in-between, thereby facilitating ventilation and heat dissipation, mounting and removal.

Exemplarily, as shown in FIG. 2B, a center-to-center distance C between adjacent second printed circuit boards on adjacent card edge connectors 100 may be approximately between 5 mm and 6 mm. Optionally, the distance C may be approximately between 5.2 mm and 5.6 mm. Optionally, the distance C may be approximately between 5.4 mm and 5.5 mm. With this configuration, the adjacent card edge connectors 100 may occupy less space. Moreover, the adjacent card edge connectors 100 may have gaps between them, thereby facilitating ventilation and heat dissipation, mounting and removal. When the add-in cards inserted into a card edge connector 100 sway, the risk of affecting an adjacent add-in card 920 is reduced.

Exemplarily, as shown in FIG. 2B, the interval E between adjacent card edge connectors 100 may be approximately between 0.5 mm and 1.0 mm. Optionally, the interval E may be approximately between 0.5 mm and 0.8 mm. Optionally, the interval E may be approximately between 0.5 mm and 0.6 mm.

Exemplarily, the plurality of second printed circuit boards may be perpendicular to the first printed circuit board 910, as shown in FIG. 1 and FIGS. 2A-2B. The plurality of second printed circuit boards may extend in the longitudinal direction X-X parallel to the first printed circuit board 910. The plurality of second printed circuit boards may be disposed side by side in the transverse direction Y-Y. With this configuration, the card edge connector 100 can be a vertical connector.

Referring back to FIGS. 7-13, exemplarily, the insulating housing 200 may comprise a body 250 extending in the longitudinal direction X-X and two towers 260. The two towers 260 may be connected to two opposed ends of the body 250 in the longitudinal direction X-X. The two towers 260 may protrude from the body 250 in the vertical direction Z-Z. The plurality of slots 210 may extend from the body 250 into the two towers 260. The plurality of latches 300 may be pivotably connected to the two towers 260. In this way, the latches 300 and the towers 260 may easily lock the ends of the add-in card 920, thereby improving the stability of the connection of the add-in cards 920 to the card edge connector 100. The aforementioned latch mounting recesses 230, the first pivot holes 231a, the second pivot holes 231b, and the passageways 240 may all be provided in the towers 260.

Exemplarily, each tower 260 may be provided with a reinforcing member 500. The reinforcing member 500 may have an opening 501. Corresponding ends of the plurality of slots 210 may extend into the opening 501. Exemplarily, each tower 260 may have a plurality of the reinforcing member 500. An end of each of the slots 210 may extend into an opening 501 of a corresponding reinforcing member 500. In the embodiment as shown in the drawing, each tower 260 may have a single reinforcing member 500. Corresponding ends of the slots 210 may all extend into the opening 501 of the reinforcing member 500. The reinforcing member 400 may be made of a material with greater strength, such as plastic, ceramic, metal, and the like. Optionally, the reinforcing member 400 may be made of metallic material. Metallic material has greater strength and lower material and processing costs. Optionally, the reinforcing member 400 is a sheet metal piece. In this way, the reinforcing member 400 has greater strength and is simple and less costly to manufacture.

Thus provided, when the add-in cards 920 are inserted into the slots 210, the tower 260 can be strengthened by providing the reinforcing member 500 to enhance the impact resistance. In this way, the reinforcing member 500 can maintain the shape of the tower 260 from two sides of the add-in cards 920 in the transverse direction Y-Y, thereby avoiding deformation, or even cracking, of the body 250 and the tower 260 when the add-in cards 920 are subjected to an external impact.

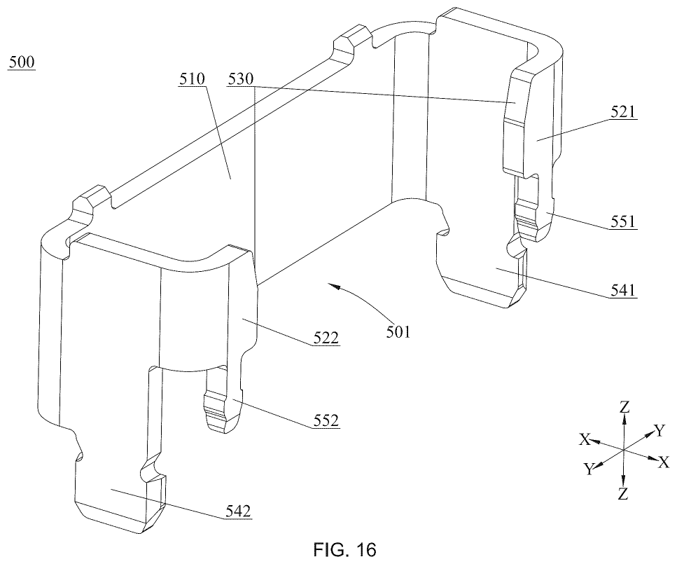

Exemplarily, as shown in FIG. 16, each reinforcing member 500 may be C-shaped. The reinforcing member 500 may at least partially surround corresponding ends of the plurality of slots 210. Exemplarily, the C-shaped reinforcing member 500 may include a U-shaped reinforcing body 510, as well as a first hook 521 and a second hook 522 connected to two sides of the reinforcing body 510. The first hook 521 and the second hook 522 may be bent inwardly from the mouth of the U-shape, respectively, with the first hook 521 and the second hook 522 defining the opening 501. With this configuration, the reinforcing member 500 can form a structure like encircling the tower 260, which can further strengthen the tower 260 and enhance its impact resistance. Particularly in the case where the reinforcing member 500 is required to encircle the ends of the plurality of slots 210, the plurality of add-in cards 920 may generate a greater transverse impact force when swaying. The first hook 521 and the second hook 522 may enhance the mechanical strength of the reinforcing body 510, thereby ensuring the stability of the plurality of add-in cards 920.

Optionally, the reinforcing member 500 may also be U-shaped, without the first hook 521 and the second hook 522.

The tower 260 may be provided with a groove 290. The reinforcing member 500 may be inserted into the groove 290. The reinforcing member 500 may be inserted into the groove 290 in the vertical direction Z-Z. In the vertical direction Z-Z, the groove 290 may extend to the top surface of the tower 260. The reinforcing member 500 may be inserted into the groove 290 from the top surface of the tower 260. The insulating housing 100 and the reinforcing member 500 may be assembled after being manufactured in separate pieces, thereby facilitating manufacturing and mounting, and lowering the costs of the card edge connector 100.

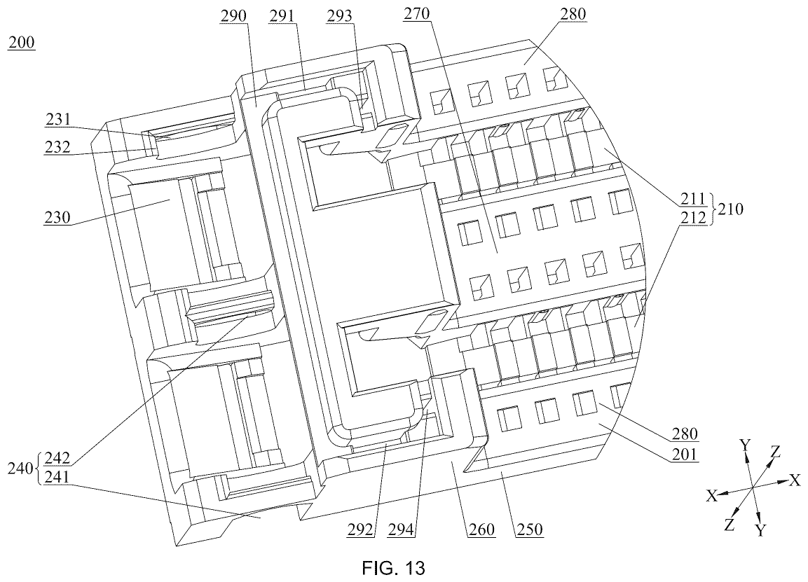

Exemplarily, the reinforcing member 500 may further include a first body extension 541 and a second body extension 542 extending from the reinforcing body 510 toward the mounting face 202, as shown in conjunction with FIGS. 13 and 16. The first body extension 541 and the second body extension 542 may be disposed on both sides of the plurality of slots 210 in the transverse direction Y-Y. A first positioning portion 291 and a second positioning portion 292 may be disposed correspondingly at the bottom of the groove 290. The first body extension 541 and the second body extension 542 may be inserted into the first positioning portion 291 and the second positioning portion 292, respectively. The extensions may be secured to the corresponding positioning portions by interference fit. By providing these extensions and positioning portions, not only can the reinforcing members 500 be securely mounted to the tower 260, but also the vertical direction Z-Z dimension of the reinforcing members 500 can be extended as much as possible, so that the tower 260 can be protected from deformation or cracking to a greater extent.

Exemplarily, the reinforcing member 500 may further include a first hook extension 551 and a second hook extension 552 extending from the first hook 521 and the second hook 522, respectively, toward the mounting face 202, as shown in conjunction with FIGS. 13 and 16. The first hook extension 551 and the second hook extension 552 may be disposed on two sides of the plurality of slots 210 opposed in the transverse direction Y-Y. A third positioning portion 293 and a fourth positioning portion 294 may be disposed correspondingly at the bottom of the groove 290. The first hook extension 551 and the second hook extension 552 may be inserted into the third positioning portion 293 and the fourth positioning portion 294, respectively. The extensions and the corresponding positioning portions may be secured to each other by interference fit. By providing these extensions and positioning portions, not only can the reinforcing members 500 be securely mounted to the tower 260, but also the vertical dimension of the reinforcing members 500 can be extended as much as possible, so that the tower 260 can be protected from deformation or cracking to a greater extent.

Optionally, the tops of the first hook 521 and the second hook 522 may be provided with chamfers 530. The chamfers 530 may serve as guides, and the chamfers 530 may avoid scratching the add-in cards 920 when the add-in cards 920 are inserted into the slots 210 in the vertical direction Z-Z.

Exemplarily, locking ends 330 of the latches 300 of the same tower 260 are directly adjacent to each other in the transverse direction Y-Y. No other components are provided between adjacent locking ends 330 on this tower 260. In order to be adapted to existing standard DDR5 connectors, the transverse dimension of the locking ends 330 cannot be reduced indefinitely. In this case, the locking ends 330 of the same tower 260 directly adjacent to each other can reduce the transverse dimension of the insulating housing 200. Optionally, there may be a certain gap between adjacent locking ends 330 to allow one of the latches 300 to pivot without impacting an adjacent latch 300. And the overall dimension of these locking ends 330 matches the dimension of this tower 260 in the transverse direction Y-Y. This configuration aims to minimize the transverse dimension of the insulating housing 200.

Exemplarily, a plurality of recessed chambers 261 may be disposed in each tower 260 that are in one-to-one correspondence with the plurality of slots 210, as shown in FIGS. 11-12. A first projection 262 may be provided on the sidewall of each of the plurality of recessed chamber 261. The connecting portion 340 of each latch 300 may be provided with a lug 341. The lug 341 may include a second projection 342. When the latch 300 is in the locked position, the lug 341 thereof is inserted into the corresponding recessed chamber 261. The second projection 342 may be engaged to the first projection 262 such that the corresponding latch 300 is disposed in the insulating housing 200. With this configuration, the latch 300 can be retained in the locked position after being disposed in the insulating housing 200, which can improve the connection stability of the add-in card 920 with the card edge connector 100.

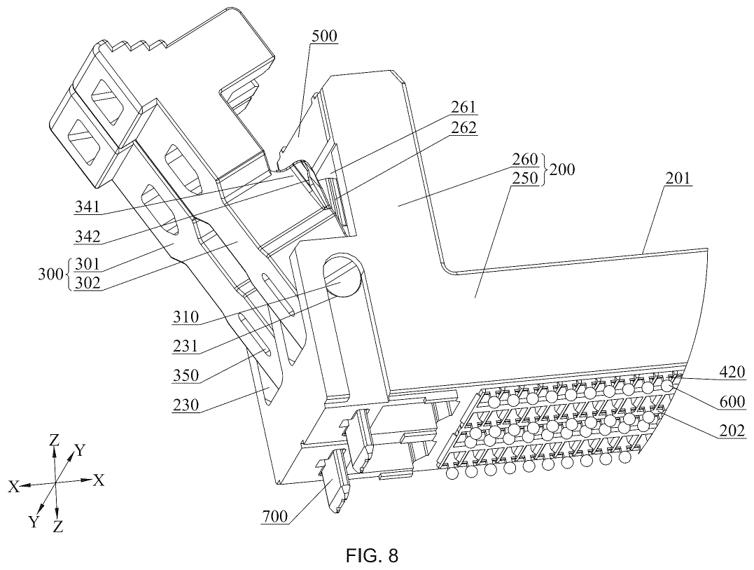

Exemplarily, each recessed chamber 261 extends to the corresponding slot 210 in the longitudinal direction X-X. Heat dissipation can thereby be enhanced. The latch 300 may be provided with a heat dissipation hole 350, as shown in FIGS. 8 and 15, and heat generated by the add-in card 920 may be diffused to the outside via the heat dissipation hole 350. Since the space between adjacent add-in cards 920 inserted into a card edge connector 100 is smaller, connecting the recessed chamber 261 with the corresponding slot 210 and latch mounting recess 230 can increase the sectional area of the recessed chamber 261 perpendicular to the longitudinal direction X-X, and thus to enhance its heat dissipation performance. Optionally, due to the larger sectional area of the recessed chamber 261, the mechanical strength of the tower 260 may be reduced. In this case, the reinforcing member 500 is particularly important. The ends of the plurality of slots 210 all extend into the reinforcing members 500, which may enable the reinforcing members 500 to provide reinforcement to the towers 260 in the transverse direction Y-Y, thereby ensuring the mechanical strength of the towers 260.

The inventors have also recognized and appreciated designs for a mounting interface between a connector and a circuit board that can improve signal integrity when dense signals are transmitted at high speed. The techniques described herein may enable narrower terminals being soldered to bigger contact pads, which can better match the impedance of the connector to a memory card inserted in a slot of the connector (and/or the circuit board to which the connector is mounted). Better impedance match can enable the connector to operate at higher speeds and/or with leass signal distortion and therefore improve signal integrity. Further, having circular contact pads on the printed circuit board can provide more flexibility for routing from the pads. Exemplarily, the card edge connector 100 may further include a plurality of solder balls 600, as shown in FIGS. 17-18. Each of the plurality of solder balls 600 may be connected to the mounting end 420 of a corresponding conductive element 400. The mounting end 420 may be soldered to the contact pad 913 on the first printed circuit board 910 via the solder ball 600. In this way, the add-in card 920 may be electrically connected to the first printed circuit board 910 via the card edge connector 100. The solder ball 600 may be made of any suitable metallic materials, such as tin. Compared to an SMT process by which a standard DDR5 connector is soldered to the pads on the motherboard, Ball Grid Array (BGA) technology may reduce a transverse dimension occupied by the mounting ends 420 within the footprint 911 on the first printed circuit board 910. The space between adjacent slots 210 in the card edge connector 100 can be further reduced. As previously described, two rows of conductive elements 400 are disposed in the inner wall 270 between adjacent slots 210, and the transverse dimension of the mounting ends 420 of the two rows of conductive elements 400 has a direct impact on the transverse dimension of the card edge connector 100.

Moreover, for the card edge connector 100 with high transmission rate and high density, it is particularly important to improve its signal integrity. The Inventors have recognized and appreciated design techniques that enable a smaller solder area at interfaces between the mounting ends 420 of the card edge connector 100 and the first printed circuit board 910, which can improve signal integrity. Exemplarily, the intermediate portion 430 of each of the plurality of conductive elements 400 extends beyond two opposite sides of the respective mounting end 420 in the longitudinal direction X-X. Exemplarily, each conductive element 400 may include cuts 440 disposed on opposite sides of respective mounting end 420 in the longitudinal direction X-X. The cuts 440 are enclosed by the intermediate portion 430 and the mounting end 420. The mounting end 420 of each of the plurality of conductive elements 400 may include a flat surface 421. Such a mounting end 420 may enable a solder ball 600 having a larger diameter to be attached. Each solder ball 600 may be attached to the flat surface 421 of the mounting end 420 of the corresponding conductive element 400. The dimension of the flat surface 421 of the mounting end 420 of each conductive element 400 in the longitudinal direction X-X may be smaller than the diameter of the solder ball 600. In this way, melted solder material of the solder ball 600 may fill the cuts 440 formed between the intermediate portion 430 and the mounting end 420 during reflow, thereby forming a smaller soldering area to the surface of the first printed circuit board 910 than not having the cuts 440. Such a configuration can reduce impedance change at the mounting end due to, for example, the additional of solder materials. Further, filling the cuts 440 with melted solder material may increase the tolerance of errors in the manufacturing process. For example, while existing surface mount tails may tolerate a maximum of 0.1 mm variation in coplanarity, the mounting end 420 described herein may tolerate 0.2 mm variation in coplanarity.

Exemplarily, the dimension of the intermediate portion 430 of each conductive element 400 in the longitudinal direction X-X may be larger than the diameter of the solder ball 600. Each conductive element 400 may be secured to the insulating housing 200 by the intermediate portion 430, and the dimension of the intermediate portion 430 in the longitudinal direction X-X is large enough to ensure the connection strength of the conductive element 400 to the insulating housing 200. The longitudinal dimension of the intermediate portion 430 may be large enough to block the melted solder material during reflow from entering into the interior of the insulating housing 200. The intermediate portion 430 may restrain the melted solder material from flowing to undesired positions to affect the impedance of the conductive element 400.

Exemplarily, in the longitudinal direction X-X, the center of the mounting end 420 of each conductive element 400 is aligned with the center of the respective intermediate portion 430. In this way, the cuts 440 formed on opposite sides of each mounting end 420 can be of the same size. In this way, for a standard connector such as DDR5, where the longitudinal dimension of the intermediate portion 430 may be prescribed, having the mounting end 420 to be aligned with the intermediate portion 430 centrally may enable relatively larger cuts 440 on both sides, thereby avoiding melted solder material in a smaller cut 440 from adhering to the first printed circuit board 910. As previously mentioned, increasing the soldering areas between the mounting ends 420 and the first printed circuit board 910 are not desirable for improving signal integrity.

In the illustrated embodiment, the mounting end 420 extends from the intermediate portion 430 in the vertical direction Z-Z. The mounting end 420 may be in the shape of a straight rod. In this case, an end surface of the mounting end 420 perpendicular to the vertical direction Z-Z forms the flat surface 421. In other embodiments not shown, the mounting end 420 may have other shapes, such as an L-shape as in SMT technology, and for example, the mounting end 420 of each conductive element 400 may include an extension that extends in the transverse direction Y-Y. In this configuration, the flat surface 421 may be disposed on the extension. The solder ball 600 may be connected to the flat surface 421. Each extension may have a certain length in the transverse direction Y-Y. The length may be small to avoid the extension of the conductive element 400 on the outer wall 280 from extending beyond the outer side surface 203 of the insulating housing 200 in the transverse direction Y-Y. In addition, the length may be small enough, enabling the mounting ends 420 of the two rows of conductive elements 400 on the inner wall 270 to electrically insulate from each other. In the transverse direction Y-Y, such mounting ends 420 are shorter than the mounting ends used in, for example, DDR5 standard connectors, thereby improving signal integrity.

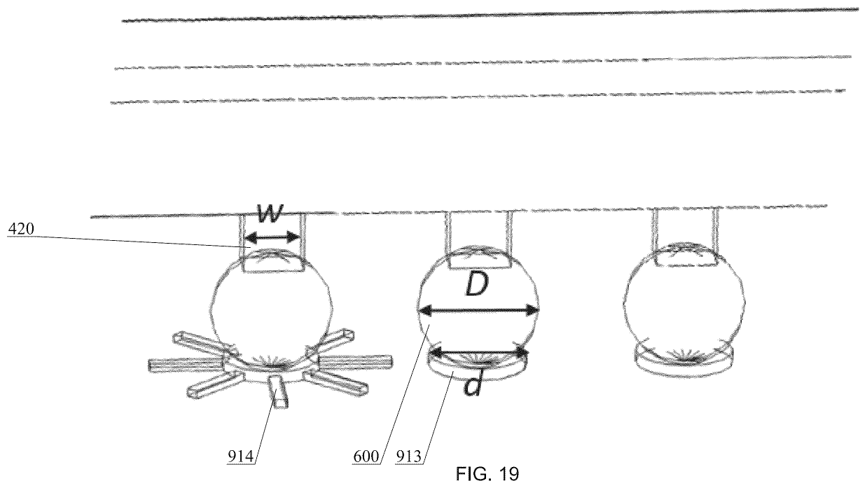

Additionally, signal integrity may be improved by using circular contact pads. A plurality of contact pads 913 may be disposed on the first printed circuit board 910, and a plurality of conductive elements 400 on each card edge connector 100 may be electrically connected to the plurality of contact pads 913 in one-to-one correspondence. Exemplarily, each contact pad 913 may be circular in shape, as shown in FIG. 19. A diameter d of the contact pads 913 may be smaller than the diameter D of the solder balls 600, and a width w (e.g., the longitudinal dimension) of the mounting ends 420 may be smaller than the diameter d of the contact pads 913. The diameter d of the contact pads 913 being smaller than the diameter D of the solder balls 600 reduces the size of the soldering area between them. Optionally, the circular contact pads 913 of the first printed circuit board 910 may provide improved convenience for conductive traces 914 extending from the contact pads. Moreover, the said convenience may be more significant in the case where a plurality of conductive traces 914 are connected to a single contact pad 913. The conductive traces 914 may be electrically connected to the circular contact pad 913 at any suitable angle. Some schematic angles are shown in the drawing. In addition, the conductive traces 914 substantially have same contact area with the circular contact pad 913, so that the plurality of conductive traces 914 connected to different circular contact pads 913 can have uniform and stable connection impedance. And it is also possible to reduce the limitation to the layout in the first printed circuit board 910, providing more flexibility for routing from the pads.

Referring back to FIG. 2B, for a single card edge connector, the interval between the mounting ends of the two rows of conductive elements disposed in the inner wall between two adjacent slots is reduced. Correspondingly, a center-to-center distance P1 between the contact pads 913 on a same side of the first printed circuit board 910 for connecting these two rows of conductive elements may be smaller. Exemplarily, the center-to-center distance P1 may be approximately between 0.92 mm and 1.0 mm. Optionally, the center-to-center distance P1 may be approximately between 0.92 mm and 0.96 mm. Optionally, the center-to-center distance P1 may be approximately between 0.92 mm and 0.94 mm. For a single card edge connector 100, the mounting ends 420 of the two rows of conductive elements 400 on two opposite sides of each card 210 may have a larger interval therebetween. Correspondingly, a center-to-center distance P2 between the contact pads 913 on the first printed circuit board 910 connecting these two rows of conductive elements may be larger. Exemplarily, the center-to-center distance P2 may be approximately between 3.2 mm and 3.6 mm. Optionally, the center-to-center distance P2 may be approximately between 3.25 mm and 3.4 mm. Optionally, the center-to-center distance P2 may be approximately between 3.28 mm and 3.3 mm.

The present disclosure has been described by the above embodiments, but it should be understood that a variety of variations, modifications and improvements may be made according to the teaching of the present disclosure by those skilled in the art, and all of these variations, modifications and improvements fall within the spirit and the scope of protection of the present disclosure. The scope of protection of the present disclosure is defined by the appended claims and its equivalent scope. The above embodiments are only for the purpose of illustration and description, and are not intended to limit the present disclosure to the scope of the described embodiments.

Moreover, although many creative aspects have been described above with reference to the vertical connector, it should be understood that the aspects of the present disclosure are not limited to these. Any one of the creative features, whether alone or combined with one or more other creative features, can also be used for other types of connectors, such as right-angle connectors and coplanar connectors, and the like.

In the description of the present disclosure, it is to be understood that orientation or positional relationships indicated by orientation words “front’, “rear”, “upper”, “lower”, “left”, “right”, “transverse direction”, “longitudinal direction”, “vertical direction”, “perpendicular”, “horizontal”, “top”, “bottom” and the like usually are shown based on the accompanying drawings, only for the purposes of the ease in describing the present disclosure and simplification of its descriptions. Unless stated to the contrary, these orientation words do not indicate or imply that the specified apparatus or element has to be specifically located, and structured and operated in a specific direction, and therefore, should not be understood as limitations to the present disclosure. The orientation words “inside” and “outside” refer to the inside and outside relative to the contour of each component itself.

For facilitating description, the spatial relative terms such as “on”, “above”, “on an upper surface of” and “upper” may be used here to describe a spatial position relationship between one or more components or features and other components or features shown in the accompanying drawings. It should be understood that the spatial relative terms not only include the orientations of the components shown in the accompanying drawings, but also include different orientations in use or operation. For example, if the component in the accompanying drawings is turned upside down completely, the component “above other components or features” or “on other components or features” will include the case where the component is “below other components or features” or “under other components or features”. Thus, the exemplary term “above” can encompass both the orientations of “above” and “below.” In addition, these components or features may be otherwise oriented (for example rotated by 90 degrees or other angles) and the present disclosure is intended to include all these cases.

It should be noted that the terms used herein are only for describing specific embodiments, and are not intended to limit the exemplary embodiments according to the present application. As used herein, an expression of a singular form includes an expression of a plural form unless otherwise indicated. In addition, it should also be understood that when the terms “including” and/or “comprising” are used herein, it indicates the presence of features, steps, operations, parts, components and/or combinations thereof.

It should be noted that the terms “first”, “second” and the like in the description and claims, as well as the above accompanying drawings, of the present disclosure are used to distinguish similar objects, but not necessarily used to describe a specific order or precedence order. It should be understood that ordinal numbers used in this way can be interchanged as appropriate, so that the embodiments of the present disclosure described herein can be implemented in a sequence other than those illustrated or described herein.

What is claimed is:

1. An electrical connector comprising:
a housing having a plurality of slots extending in parallel to each other, each of the plurality of slots configured for receiving a respective mating component; and
a plurality of latches pivotably connected to the housing so as to pivot between a locked position and an unlocked position,
wherein each of the plurality of slots has a latch of the plurality of latches disposed at an end of the slot and configured for retaining the mating component in the slot when the latch is in the locked positon and releasing the mating component from the slot when the latch is in the unlocked position.

2. The electrical connector of claim 1, wherein:
each of the plurality of slots is configured for receiving a DDR card; and
adjacent slots of the plurality of slots have a center-to-center distance between 4.2 mm and 5.4 mm.

3. The electrical connector of claim 1, wherein:
the housing comprises a body extending in a longitudinal direction and a tower disposed at an end of the body and extending from the body in a vertical direction perpendicular to the longitudinal direction;
the plurality of slots extend from the body into the tower; and
the plurality of latches are pivotably connected to the tower.

4. The electrical connector of claim 3, further comprising:
a reinforcing member disposed at an end of the tower,
wherein the reinforcing member comprises a U-shaped body surrounding ends of the plurality of slots.

5. The electrical connector of claim 4, wherein:
the reinforcing member comprises an opening; and
the plurality of slots extend into the opening of the reinforcing member.

6. The electrical connector of claim 3, wherein:
the tower comprises a plurality of chambers corresponding to the plurality of latches, respectively, and a plurality of first projections each extending into a respective chamber of the plurality of chambers; and
each of the plurality of latches comprises a second projection configured to engage a respective first projection when the latch is in the locked position.

7. The electrical connector of claim 1, wherein:
the housing comprises a plurality of sidewalls at an end and a plurality of recesses between adjacent sidewalls of the plurality of sidewalls; and
each of the plurality of latches is disposed in a recess of the plurality of recesses and povitably connected to respective sidewalls.

8. An electrical connector, comprising:
a housing having a plurality of slots extending in parallel to each other, each of the plurality of slots configured for receiving a mating component; and
a plurality of conductive elements held by the housing, each of the plurality of conductive elements comprising a mating end having a mating contact portion curving into a slot of the plurality of slots, a mounting end opposite the mating end, and an intermediate portion joining the mating end and the mounting end, wherein, for each of the plurality of conductive elements;
the mounting end is narrower than the intermediate portion and disposed such that the intermediate portion extends beyond opposite sides of the mounting end; and
the mounting end comprises a flat surface configured for a solder ball attached thereto.

9. The electrical connector of claim 8, further comprising:
a plurality of solder balls attached to respective mounting ends of the plurality of conductive elements.

10. The electrical connector of claim 9, wherein, for each of the plurality of conductive elements:
the flat surface is narrower than a diameter of the solder ball.

11. The electrical connector of claim 8, wherein:
each of the plurality of conductive elements comprises a pair of cuts disposed on opposite sides of the mounting end.

12. The electrical connector of claim 8, wherein:
each of the plurality of slots is configured for receiving a DDR card; and
adjacent slots of the plurality of slots have a center-to-center distance between 4.2 mm and 5.4 mm.

13. The electrical connector of claim 8, wherein:
the housing comprises a first wall between adjacent slots of the plurality of slots;
the first wall has a thickness between 2.5 mm and 3 mm in a direction perpendicular to a direction in which the plurality of slots extend;
the housing comprises a second wall disposed on an outermost side of the plurality of slots; and
the outer wall has a thickness between 1.7 mm and 1.75 mm.

14. The electrical connector of claim 8, comprising:
at least one latch pivotably connected to the housing so as to pivot between a locked position and an unlocked position.

15. An electronic system comprising:
a first printed circuit board having a plurality of contact pads; and
a plurality of electrical connectors mounted on the first printed circuit board, each of the plurality of electrical connectors comprising:
a plurality of conductive elements electrically connected with respective contact pads of the plurality of contact pads of the first printed circuit, and
a plurality of slots extending in parallel to each other, each of the plurality of slots configured for receiving a second printed circuit board.

16. The electronic system of claim 15, wherein:
a center-to-center distance between two adjacent slots of adjacent electrical connectors is larger than a center-to-center distance between two adjacent slots of the same connectors, such that pitch of the second printed boards is not uniform.

17. The electronic system of claim 16, wherein:
the center-to-center distance between the two adjacent slots of the same connectors is between 4.2 mm and 5.4 mm; and
the center-to-center distance between the two adjacent slots of adjacent electrical connectors is between 5 mm and 6 mm.

18. The electronic system of claim 15, wherein:
the plurality of contact pads are circular contact pads.

19. The electronic system of claim 15, wherein, for each of the plurality of electrical connectors:
contact pads in two adjacent rows have a center-to-center distance between 0.9 mm and 1.0 mm.

20. The electronic system of claim 15, wherein:
the first printed circuit board has a length in a transverse direction perpendicular to a longitudinal direction in which the plurality of slots extend;
the plurality of electrical connectors comprises at least twenty-four electrical connectors disposed within the footprint of the first printed circuit board;
the electronic system further comprises two processors disposed within the footprint of the first printed circuit board; and
the length of the first printed circuit board is between 480 mm and 490 mm.
